(19) United States
(12) Patent Application Publication
(10) Pub. No.: US 2016/0148868 A1
(43) Pub. Date: May 26, 2016

(54) PRECISION INTRALEVEL METAL CAPACITOR FABRICATION

(71) Applicant: International Business Machines Corporation, Armonk, NY (US)

(72) Inventors: Karl R. Erickson, Rochester, MN (US); Phil C. Paone, Rochester, MN (US); David P. Paulsen, Dodge Center, MN (US); John E. Sheets, II, Zumbrota, MN (US); Gregory J. Uhlmann, Rochester, MN (US)

(21) Appl. No.: 14/552,533

(22) Filed: Nov. 25, 2014

(51) Int. Cl. H01L 23/522; H01L 49/02

(52) U.S. Cl. CPC H01L 23/5222; H01L 28/40; H01L 23/5226

(57) ABSTRACT

A method for fabricating, within an integrated circuit (IC), a capacitor that includes a first plate formed within a recess of a metal layer that includes a second plate of the capacitor is disclosed. The method may include forming the second plate of the capacitor by creating, in a top surface of the metal layer, the recess having at least one side and a bottom and depositing a conformal dielectric film onto the at least one side and the bottom of the recess. The method may also include forming the first plate of the capacitor by filling a portion of the recess that is not filled by the conformal dielectric film with an electrically conductive material that is electrically insulated, by the conformal dielectric film, from the second plate.

### BACKGROUND

The present disclosure generally relates to integrated circuits (ICs). In particular, this disclosure relates to fabricating a precision capacitor in a metal wiring plane of an IC.

A capacitor is a passive electrical component having at least two electrical conductors (plates) separated by a dielectric (i.e., insulator), which may be used to electrostatically store energy in an electric field. Capacitors may be useful and implemented within a variety of types ICs, particularly analog integrated circuits.

The structure of a capacitor formed in an IC may include low ohmic connections that enable electrical and physical connection of the capacitor to conductors and/or other circuit elements within the IC. A capacitor may have a value tolerance which may be a limited allowable deviation from a designed or specified capacitance value. Capacitor tolerances may be specified as a percent of the specified target capacitance value, for example 10%. Circuits employing capacitors with relatively small tolerance values may perform and produce outputs with greater predictability than circuits employing capacitors with larger tolerances.

### SUMMARY

Various aspects of the present disclosure may be useful for creating a precision capacitor having a predictable and consistent capacitance value, for use as a circuit element within an integrated circuit (IC). An IC designed according to embodiments of the present disclosure may include circuits that perform with enhanced precision and consistency.

Various aspects of the present disclosure may be useful for integrating a high precision, high storage density and low resistance capacitor into an IC. A capacitor configured according to embodiments of the present disclosure may be implemented within a single metal layer of an IC and may offer simplified wiring, lower parasitic resistance, and a smaller layout area than other types of IC capacitors.

Embodiments may be directed towards a method for fabricating, within an integrated circuit (IC), a capacitor that includes a first plate formed within a recess of a metal layer that includes a second plate of the capacitor. The method may include forming the second plate of the capacitor by creating, in a top surface of the metal layer, the recess having at least one side and a bottom, and depositing a conformal dielectric film onto the at least one side and the bottom of the recess. The method may also include forming the first plate of the capacitor by filling a portion of the recess that is not filled by the conformal dielectric film with an electrically conductive material that is electrically insulated, by the conformal dielectric film, from the second plate.

Embodiments may also be directed towards a capacitor, within a metal layer of, and for use with, an integrated circuit (IC). The capacitor may include a first plate that includes at least one side and a bottom of a recess in a top surface of the metal layer and a conformal dielectric film attached to the at least one side and the bottom of the recess. The capacitor may also include a second plate that is electrically conductive and within a portion of the recess that is not filled by the conformal dielectric film and that is electrically insulated from the first plate by the conformal dielectric film.

Aspects of the various embodiments may be used to fabricate a capacitor having precisely controlled physical dimensions, which may result in the capacitor having a small capacitance tolerance value. Aspects of the various embodiments may also be useful for creating an area-efficient capacitor that may be easily accessible and customizable in an existing conductor layer of an IC.

Aspects of the various embodiments may be used to conserve layout space within an IC design by creating a precision capacitor within back-end-of-line (BEOL) interconnect structures. Aspects of the various embodiments may also be useful for providing cost-effective high-precision capacitors for use with ICs, by using existing and proven materials, design techniques and semiconductor fabrication technologies.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 includes a top view and a cross-sectional view of a precision integrated circuit (IC) capacitor, including a dielectric layer between two conductive plates, according to embodiments of the present disclosure.

FIG. 1A includes a cross-sectional view of a precision IC capacitor, including interconnecting vias and metal wires, according to embodiments of the present disclosure.

FIG. 1B is an isometric drawing of an IC, including a substrate, a dielectric layer and a metal layer, according to embodiments of the present disclosure.

FIG. 2 is a flow diagram illustrating steps for fabricating a precision IC capacitor, according to embodiments consistent with the figures.

FIG. 3 includes a set of six cross-sectional views and a set of six top views, each set illustrating the results of process steps for fabricating a precision IC capacitor, according to embodiments consistent with the figures.

FIG. 4 illustrates multiple design structures including an input design structure that is preferably processed by a design process.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

In the drawings and the Detailed Description, like numbers generally refer to like components, parts, steps, and processes.

### DETAILED DESCRIPTION

Certain embodiments of the present disclosure can be appreciated in the context of providing precision capacitors for use within particular circuits within an integrated circuit (IC) such as tank, resonant clocking, charge pump and phase-locked loop (PLL) circuits. Such circuits may be used to provide clock signals having tightly controlled frequency, skew and jitter parameters to other circuits within the IC. Such ICs may include, but are not limited to microprocessors, radio-frequency (RF), analog and mixed-signal ICs. While not necessarily limited thereto, embodiments discussed in this context can facilitate an understanding of various aspects of the disclosure. Certain embodiments may also be directed towards other equipment and associated applications, such as providing precision capacitors for use within particular circuits within an IC such as analog filter and amplifier circuits. Such circuits may be used to provide frequency-dependent filtering and general signal amplification functions within an IC. Embodiments may also be directed towards providing high-density capacitors for use in decoupling power supply voltages within an IC, such as a microprocessor, memory or analog IC.

Certain embodiments may relate to the formation of precision capacitors within an IC for use in analog circuits. The accuracy of an analog circuit, for example, one that amplifies or filters a voltage signal, may depend directly on the precision of a particular capacitor value. In some applications, chip I/O pin count and electrical parasitic limitations may make interconnection of circuit elements within the IC to capacitors external to the IC impractical.

A capacitor may be formed within an integrated circuit, for example, in an isolated diffusion layer (moat) and may have connections (to each plate structure) that allow it to be connected to other circuit elements. Capacitors formed using diffusion layers may exhibit relatively large capacitive tolerances as a result of the combined effects of several factors, and in some applications a diffusion capacitor tolerance may be as high as 30% of its specified capacitance value. Factors contributing to high capacitance variability may include, but are not limited to, implant depth and dopant concentration variations and implant region width/length variations. Parasitic resistance (also known as “equivalent series resistance” or ESR) resulting from certain types of capacitor plate connections may degrade or otherwise adversely affect the effective capacitance value of a diffusion capacitor. Capacitors formed using diffusion layers may also have relatively low capacitive density, have relatively high resistance connections, and may be difficult to connect to other circuit elements within an IC.

Diffusion area capacitors may consume large amounts of silicon area in regions that may be used for active devices such as transistors, and may be specified to have increased physical dimensions to offset large dimensional tolerances. The ongoing trends of shrinking transistor sizes, vertical field-effect transistors (e.g., FinFETs) and other silicon area constraints make diffusion area capacitors relatively costly with respect to the silicon area they may consume.

Circuits requiring precisely controlled output signals may be designed using capacitors with relatively large tolerances, however, design techniques often involve the use of supplementary active devices (transistors, diodes) and matching of the values of two or more similar capacitors, fabricated near each other on the IC. These techniques may result in greater silicon area consumption than design techniques involving capacitors with low tolerances.

The relatively high permittivity values of various dielectric materials such as silicon dioxide (SiO₂) or hafnium dioxide (HfO₂), may make these dielectric materials useful in the fabrication of precision IC capacitors. It may be understood that some level of material or chemical impurities may exist as a result of a process designed to deposit or form a certain type of material, such as a dielectric. For example, in a process step designed to deposit silicon dioxide (SiO₂), it can be appreciated that the material actually deposited may be substantially silicon dioxide, although some small amount of impurities may also be included, as an unintended result of the deposition process.

Certain figures herein show only a single capacitive structure, however, embodiments may include a plurality of capacitive structures, and a plurality of planar layers, each containing one or more capacitive structures. Certain embodiments may be useful for the creation of precision capacitors having matched capacitance values, resulting from similar or identical fabrication geometries. While all figures illustrate the principles and features of the present disclosure, they are not necessarily drawn to scale.

Various embodiments of the present disclosure relate to electrically capacitive structures (capacitors) that may be designed and fabricated within a single IC conductor layer (wiring plane), and thereby provide an area-efficient, capacitive circuit element having a low capacitance tolerance value. Area-efficiency may result from a small capacitor footprint located within a conductor layer that may be sparsely populated with interconnect wires. According to certain embodiments, an IC constructed with a layer including the capacitors may be compliant with existing and proven IC manufacturing processes and material sets. The layers including the capacitive structures may be particularly useful as a cost-effective way to add accessible, high precision capacitors to IC designs. An IC constructed according to embodiments of the present disclosure may be configured to be customizable late in an IC fabrication process, and to produce output signals that may be predictable and repeatable.

Capacitors formed in conductor (metal) layers above the silicon (active device) layer of an IC may be useful in allowing the IC to be customized by removing, adding or rearranging the orientation of conductors to the capacitors. These operations may be substantially less complicated than customizing capacitors formed at the device (diffusion) level, and may make an IC having these capacitors useful and versatile. Certain embodiments can be particularly useful by using aspects of known fabrication processes to create an electrically capacitive structure, which may facilitate low cost, reliable solutions not requiring substantial development time, effort or expense to implement.

For ease of discussion, the term “second plate” may be used herein, referring to one of the two plates of a precision capacitor. However, it is understood that the term “metal layer” may be used interchangeably with the term “second plate”, as the second plate is, according to embodiments, formed from a recess in the metal layer of an IC.

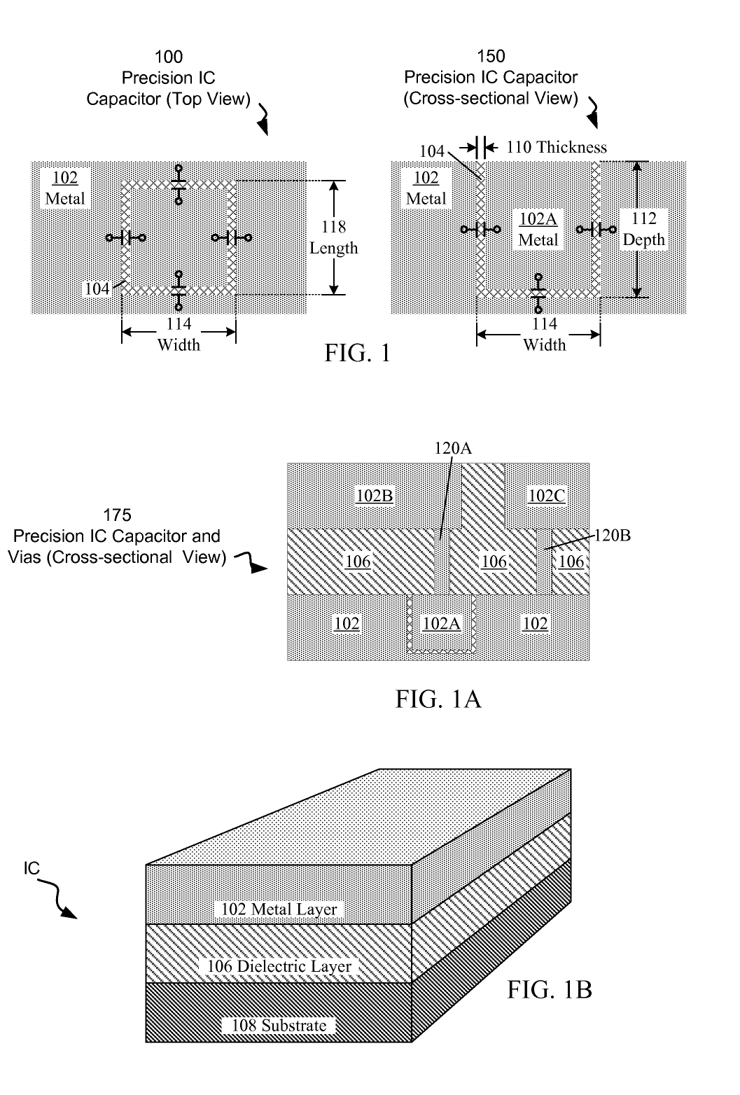

Certain embodiments relate the fabrication of a precision integrated circuit (IC) capacitor within a metal layer of an IC. FIG. 1 includes a top view 100 and a cross-sectional view 150 of a precision IC capacitor, fabricated within a metal layer 102 of an IC and including a conformal dielectric film 104 between first conductive plate 102A and second conductive plate 102, according to embodiments of the present disclosure. Capacitor 100 may be generally used as a circuit element within the IC, according to embodiments of the present disclosure. The tolerances of physical dimensions of the capacitor 100 may be closely controlled during its fabrication process, which may result in the capacitor having a precisely controlled (low deviation from a specified value) capacitance, or low capacitor tolerance.

Conformal dielectric film 104 can be used to construct the capacitor 100 and provides a physical attachment of the first plate 102A to the second plate 102. The capacitance of capacitor 100 may be substantially determined by the surface area of the first plate 102A that is separated, by the conformal dielectric film 104, from corresponding surface area of the second plate 102. In certain embodiments, low ohmic connections such as vias may be fabricated from an electrically conductive material (e.g., copper or aluminum) and may be used connect plates 102 and 102A of capacitor 100 to additional electrical conductors and circuit elements within the IC. The embodiment depicted in FIG. 1 includes the precision capacitor 100 created within a recess in the metal layer 102, which is consistent with metal traces which may be formed in metal layers to conduct signals within an IC.

Precise control of the physical dimensions (width 114, length 118, depth 112 and conformal dielectric film 104 thickness 110) of the capacitor 100 during its fabrication process may result in precisely controlled areas of at least one side and a bottom of the recess. Precisely controlled recess side and bottom dimensions may yield similarly tight control of the capacitance value of the capacitor, which may result in robust, consistent and predictable circuit performance for an IC that incorporates it. The capacitor 100 may provide performance enhancements for both analog and digital types of circuits.

In general, the capacitance of a parallel plate capacitor having a conductive plate area A, plate separation t, with terminals attached to each plate, may be determined in accordance with the following equation:

$$C = ɛ \times \frac{A}{t} = k {ɛ}_{0} \times \frac{A}{t}$$

Where:

C=the capacitance of the precision capacitor (Coulomb/Volt)

∈=the relative permittivity of the dielectric material used in the capacitor

A=plate area of the capacitive element (m²)

t=distance between the plates (m) (consistent with thickness 110, FIG. 1)

k=relative permittivity of the dielectric material between the plates
(k=1 for free space, k>1 for all media, approximately 1 for air)

∈₀=permittivity of free space=8.854×10⁻¹² F/m (farads per meter)

According to embodiments, the conductive plate area A of a precision IC capacitor may be determined in accordance with the following equation:

A=2(wd+ld)+wl

Where:

A=plate area of the first/second plates (m²)

w=plate width (m) (114, FIG. 1)

d=plate depth (m) (112, FIG. 1)

l=plate length (m) (118, FIG. 1)

The equation above includes the total capacitor area as a sum of the area of all of four sides and the bottom of the first plate structure 102A. Referring to the equations above, the relative permittivity of conformal dielectric film 104 (FIG. 1) may be the relative permittivity, for example, of a deposited film of hafnium dioxide (HfO₂).

Each of the physical dimensions (“A”, “t”, “w”, “d” and “1”) used to define a capacitive structure may be individually and accurately controlled by embodiments of the present disclosure in order to achieve precise control (low tolerance) of the structure's capacitance.

For example, in certain embodiments, a first plate (e.g., 102A) of a precision capacitor may be fabricated to within 1% of a specified length “1” (in a range between 1 μm and 1 mm), to within 3% of a specified width “w” (in a range between 10 nm and 200 nm), and to within 2% of a specified depth “d” (in a range between 200 nm and 2 μm). In certain embodiments the conformal dielectric film 104 (FIG. 1) may be fabricated to within 4% of a specified thickness “t” (in a range between 1 nm and 10 nm). The relative permittivity “6” of conformal dielectric film 104 (FIG. 1) may vary by less than 2%, in certain embodiments. Tolerances for capacitor physical dimensions (e.g., length) can be fabricated and measured relative to +/−3 sigma (σ) limits of a normal (or Gaussian) distribution of fabricated capacitor dimensions.

According to embodiments, the described dimensional and capacitive tolerances may be used to create precision IC capacitors having a tolerance of less than 6% of a specified capacitance value (in a range between 50 fF and 1 pF). Tolerances for capacitors can be measured relative to +/−3 sigma (σ) limits of a normal (or Gaussian) distribution of fabricated capacitor values.

According to embodiments, a variety of metal planes within an IC may be utilized to create a precision IC capacitor. Use of a metal plane that is relatively thick, for example, a plane that is near the top of an IC's metal plane “stack”, may result in tight control of capacitance values of precision capacitors. Use of a metal plane which is near the top of an IC's metal plane “stack” may result in reducing vertical wiring (i.e., vias) to connect a precision IC capacitor to other conductors and/or active devices, and may reduce wiring congestion near the active devices.

In certain embodiments, the second plate (e.g., 102, FIG. 1) of a precision IC capacitor may be fabricated within a wire used to connect active devices within an IC, and therefore may not have a via used specifically to interconnect it. In particular embodiments, the second plate (e.g., 102) may not be part of an interconnecting wire, and may be electrically connected to circuits within the IC through the use of at least one via contacting either a top and/or bottom surface of second plate 102.

In embodiments, the first plate (e.g., 102A) of a precision IC capacitor may be electrically connected to circuits within the IC through the use of a via contacting a top surface of the first plate (e.g., 102A).

In certain embodiments which may be useful in the design and fabrication of analog circuits, a precision capacitor having a width and length each approximately 1 μm may be formed in a metal layer that is approximately 1 μm thick. The conformal dielectric film (104, FIG. 1) may be hafnium dioxide (HfO₂), having a thickness of approximately 40 nm and a dielectric constant (k) of approximately 28.

In certain applications, embodiments of precision IC capacitors useful in the design and fabrication of analog circuits may have capacitance in a range from approximately 50 fF to approximately 0.5 pF. A variety of physical dimensions (e.g., length, width, depth and conformal dielectric film thickness) and physical properties (e.g., dielectric constant of conformal dielectric film) may be used, in embodiments, to create IC capacitors having a wide range of precisely controlled capacitance values.

A precision IC capacitor fabricated according to certain embodiments may have a capacitive density of approximately 50 times the capacitive density of a capacitor built using field-effect transistor (FET) gate or other types of IC structures. A high density precision IC capacitor may be useful for conserving IC circuit area and allowing an IC design to include a greater number of active devices and interconnecting wires than an IC design without high-density capacitors.

In certain embodiments, a precision capacitor may have a generally cubic shape, as depicted in views 100, 150 of FIG. 1. In certain embodiments, a precision capacitor may have a non-cubic shape, such as polygonal, irregular, or cylindrical. In embodiments having non-cubic shape(s), the total capacitance of the capacitor may be calculated similarly to the method described above; however, a different equation(s) may be used to calculate the area term “A”. In certain embodiments, a precision capacitor may include multiple sets of electrically connected plates, which may be useful to increase the total capacitance of the structure.

In certain embodiments, a precision capacitor may be utilized for decoupling power supply voltages, and in certain embodiments may be used in conjunction with other electrical signal types. A precision IC capacitor may be used with electrical signals having an unknown polarity, within a voltage range that does not exceed the dielectric breakdown and/or leakage of the conformal dielectric film (e.g., 104, FIG. 1).

FIG. 1A is a cross-sectional view of a precision IC capacitor, including interconnecting vias 120A, 120B and metal wires 102B, 102C, according to embodiments of the present disclosure. In certain embodiments, vias such as 120A, 120B may be used to interconnect the first plate and the second plate 102A of a precision IC capacitor to other circuits within the IC. Vias 120A, 120B may be electrically interconnected to metal wires 102B, 102C which may be routed and electrically interconnected to other circuits, such as logic gates, FETs or other circuit nodes. In certain embodiments, at least one of the plates 102, 102A may be connected through vias and metal wires to a power supply node (e.g., VDD) or to a ground node (GND). In certain embodiments, at least one of the plates 102, 102A may be connected through vias and metal wires to a circuit node used to conduct a signal such as an analog or digital signal. Dielectric layer may be used to electrically insulate metal wires such as 102B, 102C from another metal layer (e.g., 102).

FIG. 1B is an isometric drawing of an IC, including a substrate 108, a dielectric layer 106 and a metal layer 102, according to embodiments consistent with FIG. 1,1A. The substrate 108 may be a thin slice of semiconductor material, such as a silicon crystal, used in the fabrication of integrated circuits, and may have microelectronic devices, such as transistors, fabricated within it.

Dielectric layer 106 may be formed on the top (active device) surface of substrate 108, and may be used as an insulator between metal layers and/or substrate 108. Metal layer 102 can contain electrically conductive material used to form connections between circuit elements of the IC, and is consistent with similar layers in FIG. 1, 1A, 3. FIG. 1B illustrates an embodiment of an IC; other embodiments may include additional dielectric and metal layers similar to dielectric layer 106 and metal layer 102, respectively, formed in a stacked, planar arrangement on top of a substrate (e.g., 108).

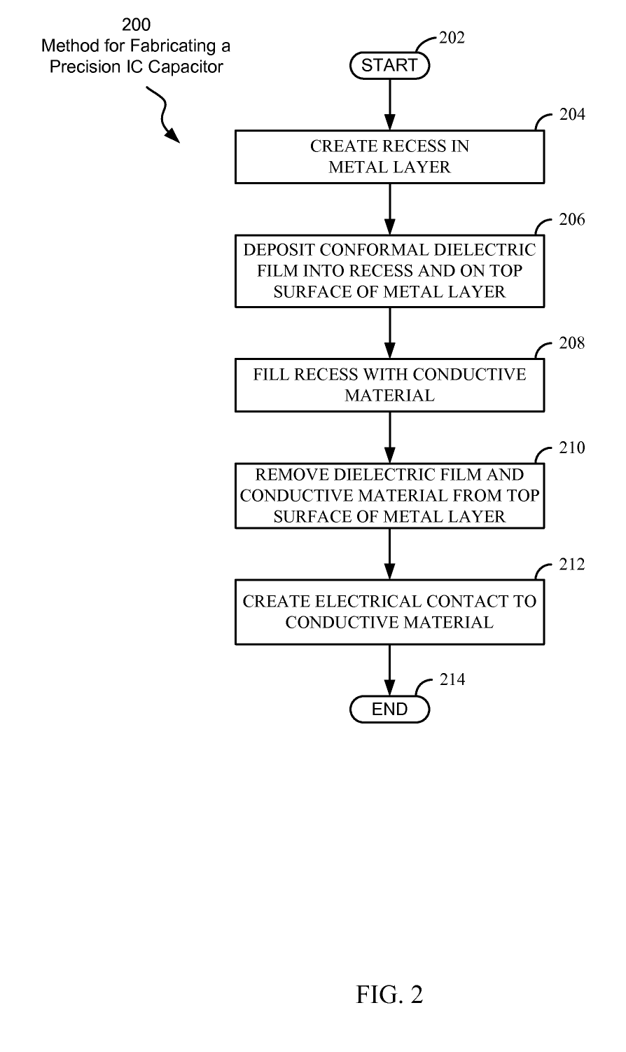

FIG. 2 is a flow diagram illustrating steps for fabricating a precision IC capacitor, according to embodiments consistent with the figures. The method for fabricating a precision IC capacitor 200 may be useful for creating capacitor structures that have precisely controlled capacitance values and that are compatible with existing IC material sets and fabrication technologies. The process 200 moves from start 202 to operation 204.

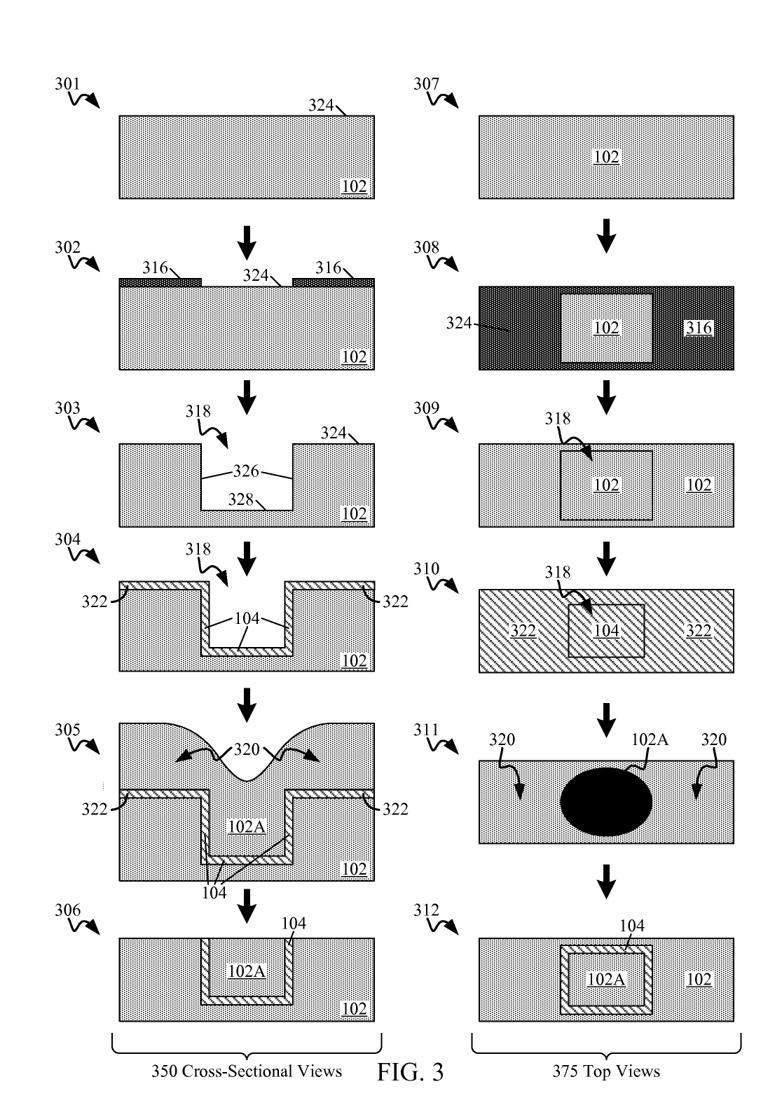

Operation 204 generally refers to the process steps that involve creating a recess 318 in a top surface (324, FIG. 3) of a metal layer 102 (view 303) which may correspond to the views 302, 303, 308 and 309 (FIG. 3) and their associated descriptions. Forming a recess through an etching process creates at least one side and a bottom of the recess (e.g., 318, FIG. 3), which may be useful as a second plate of the precision capacitor structure. Dimensions of the recess, such as width, length and depth may be calculated and specified to create a capacitor structure having a target capacitance value. Once a recess (318, view 303) has been created in the metal layer, the process moves to operation 206.

Operation 206 generally refers to the process steps that involve depositing a conformal dielectric film (104, view 304) into the side(s) and bottom of recess 318 (view 303) and onto a top surface of the metal layer 102, which may correspond to the views 304, 310 (FIG. 3) and their associated descriptions. Depositing a conformal dielectric film into the recess creates a dielectric layer, which may be useful for electrically insulating plates of a precision capacitor structure from each other. A conformal dielectric film having a relatively high dielectric constant such as hafnium dioxide (HfO₂) (k=28) may enable a precision capacitor to have a higher capacitance value than one created with a dielectric film such as silicon dioxide (SiO₂) (k=3.9). Once the conformal dielectric film has been deposited into the recess and onto the top surface of the metal layer, the process moves to operation 208.

Operation 208 generally refers to the process steps that involve filling a portion of the recess (318, view 303) that is not filled by the conformal dielectric film with an electrically conductive material, which may correspond to the views 305, 311 (FIG. 3) and their associated descriptions. Filling the recess with an electrically conductive material creates a first capacitor plate separated from the second plate by the conformal dielectric film. In certain embodiments, and IC capacitor may include more than one set of plates formed in more than one recess. Once the recess is filled, the process moves to operation 210.

Operation 210 generally refers to the process steps that involve removing the portion of the conformal dielectric film (322, FIG. 3) and the portion of the electrically conductive material (322, FIG. 3) deposited on a top surface of the metal layer (102, FIG. 3) which may correspond to the view 305, 311 (FIG. 3) and its associated description.

Removal of conformal dielectric and electrically conductive material from the surface 324 of metal layer 102 may be useful in providing a substantially planar top surface of metal layer 102, which may facilitate subsequent IC processing steps such as deposition of dielectric and metal layers. Once the portion of the conformal dielectric film and the portion of the electrically conductive material deposited on a top surface of the metal layer have been removed, the process moves to operation 212.

Operation 212 generally refers to the process steps that involve creating one or more electrical contacts to the electrically conductive material. Creation of electrical contacts to the first plate of the capacitor may be necessary to connect the plate to other circuits within the IC. Creation of electrical contacts to the second plate (102, FIG. 3) of the capacitor may be useful to connect the second plate to other circuits in embodiments having a second plate (metal layer) 102 that is physically and electrically isolated from other circuits. In embodiments that include the second plate 102 formed in a wire used as part of an IC circuit, the addition of contacts to the second plate may be optional. Once electrical contact is made to the electrically conductive material, the process 200 may end at block 214.

FIG. 3 includes a set 350 of six cross-sectional views 301-306 and a corresponding set 375 of six top views 307-312, each set depicting the results of a sequential set of process steps for fabricating a precision IC capacitor within an existing metal layer of an IC, according to embodiments consistent with the figures. The views 301-312 may be useful in illustrating details involved in creating a precision IC capacitor that has tightly controlled capacitance (low capacitor tolerance) value. The assembly steps depicted in the views 301-312 may be integrated into a back-end-of-line (BEOL) fabrication process for an IC.

Views 301 and 307 depict a metal layer 102 of an IC, prior to any processing steps to form a precision IC capacitor. Metal layer 102 may be consistent with IC metal layers used for interconnecting active devices (e.g., transistors), and may include materials such as aluminum and/or copper. In certain embodiments, metal layer 102 may be a portion of a wire used to interconnect circuits including active devices such as FETs. In certain embodiments, metal layer 102 may be a region of metal designated solely for use in creating a precision capacitor. In embodiments, the top surface 324 area (view 307) of metal layer 102 may be large enough to include a recess (318, view 309) and a “picture frame” area surrounding the recess (318, view 309). The dimensions of a minimum allowable recess (318, view 309) size and the surrounding area may depend on a particular metal layer material (e.g., aluminum) and a particular etching process (e.g., dry etch using carbon tetraflouride (CF₄) plasma) used to create the recess 318.

Views 302 and 308 depict the results of the application and patterning of a mask 316 onto a top surface 324 of the metal layer 102. Mask 316 may be used to define an area for creating (e.g., through an etching process) a recess within a metal layer 102. Mask 316 may include a material, such as a hardened photoresist, which is impervious to a particular etching process. Mask 316 may be applied on the top surface 324 of metal layer 102 using a variety of processes such as spin-coating or chemical vapor deposition (CVD), and patterned using a photolithographic process consistent with processes used for other IC fabrication steps.

Views 303 and 309 depict the results of etching of a recess 318 in a top surface 324 of metal layer 102, and the subsequent removal of mask 316 from top surface 324. The process of etching a recess 318 may be useful for creating a relatively large amount of surface area, including sides 326 and bottom 328, for a precision capacitor within a relatively small area of a metal layer 102. An etching process may be useful in creating precisely controlled dimensions such as length, width and depth of the recess 318, which may result in a precisely controlled capacitance value. Recess 318 may include at least one side 326 and a bottom 328. The recess 318 may be etched using a process such as dry etching, plasma etching or reactive ion etching. Etching agents such as carbon tetraflouride plasma (CF₄), fluorine plasma (SF₆), mixed (fluorine and chlorine) plasma (Cl₂+SF₆) and hydrogen peroxide may be used in the etching process. Other freon-based materials and chlorinated gases may also be used in the etching process. The etching process may be performed slowly, and precisely timed to produce closely controlled width, length and depth dimensions of the recess. The etching process may be designed and/or monitored in order to maintain relatively straight sides (e.g., 326) that are relatively orthogonal to top surface 324 of the metal layer 102. Following completion of the etching process, mask 316 may be removed through the use of a process involving a chemical solvent.

In certain embodiments, an etching process involving lithographic masking and wet chemical etching may be employed to create a recess in metal layer 102. Such a process may require a larger “surround” area around the formed recess 318, but may yield a similar recess structure to the use of a “dry etch” process.

Views 304 and 310 depict the results of depositing a thin conformal dielectric film 104 onto at least one side (e.g., 326, view 303) and the bottom (e.g., 328, view 303) of the recess 318. In certain embodiments, a portion 322 of thin conformal dielectric film 104 is deposited onto the top surface 324 of metal layer 102.

The thin conformal dielectric film 104 acts as the dielectric between the capacitor plates (102, 102A, view 306), and is useful for increasing the capacitance of a precision IC capacitor. Conformal dielectric film 104 may include materials such as silicon dioxide (SiO₂), silicon nitride (Si₃N₄) and hafnium dioxide (HfO₂), which may have relatively high dielectric constants (k). For example, the dielectric constants of silicon dioxide, silicon nitride and hafnium dioxide may be approximately 3.9, 7.5 and 28, respectively. Conformal dielectric film 104 may be deposited using a plasma oxidation, sputter deposition or thermal oxide growth process.

Views 305 and 311 depict the results of filling a portion of the recess 318 (view 304) that is not filled with the conformal dielectric film 104 with electrically conductive material to form the first plate 102A of the capacitor. Conformal dielectric film 104 is used to electrically insulate first plate 102A from second plate 102. In certain embodiments, a portion 320 of electrically conductive material 102A is deposited onto the top surface 324 (view 303) of metal layer 102. This portion of electrically conductive material may be deposited while filling the recess 318 (view 304) to at least the top surface 324 (view 303) of metal layer 102. Electrically conductive materials deposited to form first plate 102A may include, but are not limited to, metals such as aluminum and/or copper, and may be deposited using a process such as physical vapor deposition (PVD), sputter deposition, cathodic arc deposition or chemical vapor deposition (CVD).

Views 306 and 312 depict the result of removing the portion of the conformal dielectric film 322 and the portion 320 of the electrically conductive material deposited on a top surface (324, view 303) of the metal layer 102. Removal of a portion (320, views 305, 311) of the electrically conductive material and conformal dielectric film 322, known as planarization, may be useful for creating a substantially flat top surface on which to continue subsequent IC fabrication steps. Subsequent fabrication steps may include, but are not limited to, deposition of dielectric and/or conductive material and formation of vias used to interconnect metal layers. Planarization may include the use of a process such as a chemical-mechanical planarization (CMP) process.

In certain embodiments, a CMP process may be employed to partially planarize a portion (320, views 305, 311) of the electrically conductive material and conformal dielectric film 322, in conjunction with a subsequent “wet” (chemical) etch process to complete the deposited material removal. Use of CMP planarization followed by wet etching may be useful for reducing possible chemical contamination of metal and dielectric material layers through the use of a CMP process alone.

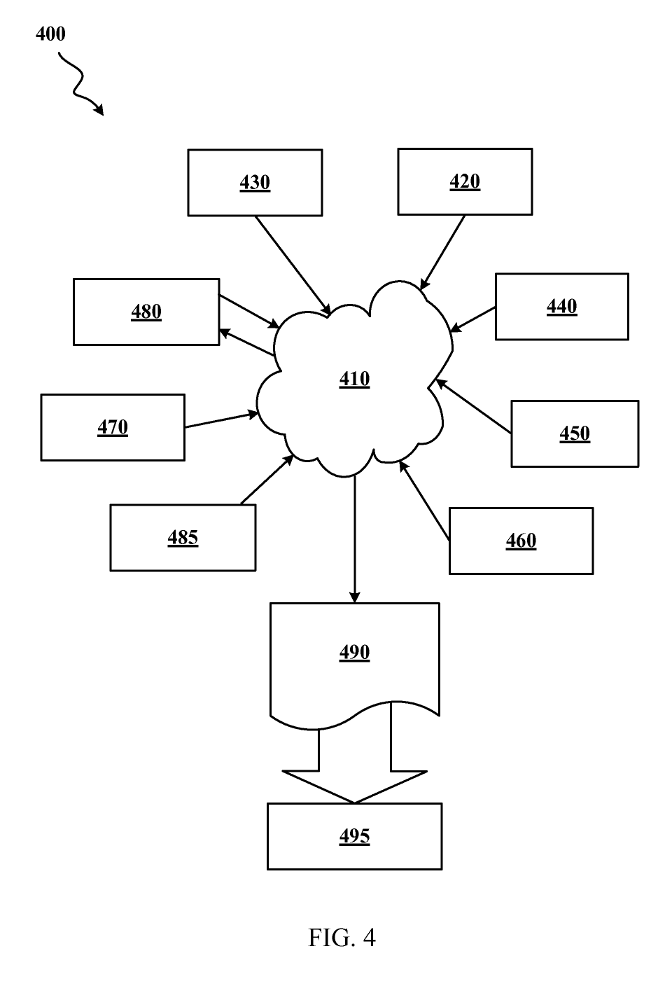

FIG. 4 illustrates multiple design structures 400 including an input design structure 420 that is preferably processed by a design process. Design structure 420 may be a logical simulation design structure generated and processed by design process 410 to produce a logically equivalent functional representation of a hardware device. Design structure 420 may alternatively include data or program instructions that, when processed by design process 410, generate a functional representation of the physical structure of a hardware device. Whether representing functional or structural design features, design structure 420 may be generated using electronic computer-aided design, such as that implemented by a core developer/designer. When encoded on a machine-readable data transmission, gate array, or storage medium, design structure 420 may be accessed and processed by one or more hardware or software modules within design process 410 to simulate or otherwise functionally represent an electronic component, circuit, electronic or logic module, apparatus, device, or system such as those shown in FIGS. 2 and 3. As such, design structure 420 may include files or other data structures including human or machine-readable source code, complied structures, and computer-executable code structures that, when processed by a design or simulation data processing system, functionally simulate or otherwise represent circuits or other levels of hardware logic design. Such data structures may include hardware-description language design entities or other data structures conforming to or compatible with lower-level HDL design languages such as Verilog and VHDL, or higher level design languages such as C or C++.

Design process 410 preferably employs and incorporates hardware or software modules for synthesizing, translating, or otherwise processing a design/simulation functional equivalent of the components, circuits, devices, or logic structures shown in FIGS. 2 and 3 to generate a Netlist 480 which may contain design structures such as design structure 420. Netlist 480 may comprise, for example, compiled or otherwise processed data structures representing a list of wires, discrete components, logic gates, control circuits, I/O devices, models, etc. that describe the connections to other elements and circuits in an integrated circuit design. Netlist 480 may be synthesized using an iterative process in which Netlist 480 is resynthesized one or more times depending on design specifications and parameters for the device. As with other design structure types described herein, Netlist 480 may be recorded on a machine-readable data storage medium or programmed into a programmable gate array. The medium may be a non-volatile storage medium such as a magnetic or optical disk drive, a programmable gate array, a compact flash, or other flash memory. Additionally, the medium may be a system or cache memory, buffer space, or electrically or optically conductive devices and materials on which data packets may be transmitted and intermediately stored via the internet, or other suitable networking means.

Design process 410 may include hardware and software modules for processing a variety of input data structure types including Netlist 480. Such data structure types may reside, for example, within library elements 430 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 440, characterization data 450, verification data 460, design rules 450, and test data files 485 which may include input test patterns, output test results, and other testing information. Design process 410 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 410, without deviating from the scope and spirit of the invention. Design process 410 may also include modules for performing standard circuit design processes such as timing analysis, verification, design rule checking, place and route operations, etc.

Design process 410 employs and incorporates logic and physical design tools such as HDL compilers and simulation model build tools to process design structure 420 together with some or all of the depicted supporting data structures, along with any additional mechanical design or data, to generate a second design structure 490. Design structure 490 resides on a storage medium or programmable gate array in a data format used for the exchange of data of mechanical devices and structures (e.g., information stored on an IGES, DXF, Parasolid XT, JT, DRG, or any other suitable format for storing or rendering such mechanical design structures). Similar to design structure 420, design structure 490 preferably comprises one or more files, data structures, or other computer-encoded data or instructions that reside on transmission or data storage media and that, when processed by an ECAD system, generate a logically or otherwise functionally equivalent form of one or more of the embodiments of the invention shown in FIGS. 2 and 3. In one embodiment, design structure 490 may comprise a compiled, executable HDL simulation model that functionally simulates the devices shown in FIGS. 2 and 3.

Design structure 490 may also employ a data format used for the exchange of layout data of integrated circuits and/or symbolic data format (e.g., information stored in a GDSII, GLI, OASIS, map files, or any other suitable format for storing such design data structures). Design structure 490 may comprise information such as symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 2 and 3. Design structure 490 may then proceed to a state 495 where, for example, design structure 490 proceeds to tape-out, is released to manufacturing, is released to a mask house, is sent to another design house, is sent back to the customer, etc.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

1-9. (canceled)

10. A capacitor, within a metal layer of, and for use with, an integrated circuit (IC), the capacitor comprising;
a first plate that includes at least one side and a bottom of a recess in a top surface of the metal layer;
a conformal dielectric film attached to the at least one side and the bottom of the recess; and
a second plate that is electrically conductive and within a portion of the recess that is not filled by the conformal dielectric film and that is electrically insulated from the first plate by the conformal dielectric film.

11. The capacitor of claim 10, wherein a width of the recess, a length of the recess, a depth of the recess and a thickness of the conformal dielectric film affect a capacitance of the capacitor.

12. The capacitor of claim 10, wherein a capacitance of the capacitor is within 6% of a specified capacitance that is in a range between 50 fF and 1 Pf.

13. The capacitor of claim 10, wherein a thickness of the conformal dielectric film is within 4% of a specified dielectric thickness that is in a range between 1 nm and 10 nm.

14. The capacitor of claim 10, wherein a width of the recess is within 3% of a specified width that is in a range between 10 nm and 200 nm.

15. The capacitor of claim 10, wherein a length of the recess is within 1% of a specified length that is in a range between 1 μm and 1 mm.

16. The capacitor of claim 10, wherein a depth of the recess is within 2% of a specified depth that is in a range between 200 nm and 2 um.

17. The capacitor of claim 10, wherein the metal layer of the IC includes at least one material from a set of materials consisting of copper and aluminum.

18. The capacitor of claim 10, wherein the electrically conductive material includes at least one material from a set of materials consisting of copper and aluminum.

19. The capacitor of claim 10, wherein the conformal dielectric film includes at least one material from a set of materials consisting of hafnium dioxide (HfO₂), silicon nitride (Si₃N₄) and silicon dioxide (SiO₂).

20. The capacitor of claim 10, further comprising at least one metal wire, electrically connected, through at least one via, to at least one plate of a group of plates consisting of: the first plate and the second plate, to connect the capacitor to a circuit within the IC.
